(19) United States
(12) Patent Application Publication
(10) Pub. No.: US 2023/0360190 A1
(43) Pub. Date: Nov. 9, 2023

(54) PROFILE DETECTION METHOD, PROFILE DETECTION PROGRAM, AND INFORMATION PROCESSING APPARATUS

(71) Applicant: Tokyo Electron Limited, Tokyo (JP)

(72) Inventor: Toshihiro KITAO, Hokkaido (JP)

(73) Assignee: Tokyo Electron Limited, Tokyo (JP)

(21) Appl. No.: 18/224,077

(22) Filed: Jul. 20, 2023

Related U.S. Application Data
(63) Continuation of application No. PCT/JP2021/042891, filed on Nov. 24, 2021.
(60) Provisional application No. 63/139,948, filed on Jan. 21, 2021.

(51) Int. Cl. G06T 7/11; G06T 7/64; G06T 7/00

(52) U.S. Cl. CPC G06T 7/0004; G06T 7/11; G06T 7/64; G06T 2207/30148

(57) ABSTRACT

A profile detection method includes a region detection step of detecting, by analyzing data of an image in which a plurality of recesses recessed in one direction are arranged in an intersecting direction with respect to the one direction, each recess region in the image, a boundary detection step of detecting a boundary of a film included in the image by analyzing the data, and a contour detection step of detecting a contour of the recess for the each recess region in the image by analyzing the data.

### CROSS-REFERENCE TO RELATED APPLICATIONS

This application is a bypass continuation application of international application No. PCT/JP2021/042891 having an international filing date of Nov. 24, 2021, and designating the United States, the international application being based upon and claiming the benefit of priority from U.S. Provisional Application No. 63/139,948, filed on Jan. 21, 2021, the entire contents of each are incorporated herein by reference.

### TECHNICAL FIELD

The present disclosure relates to a profile detection method and an information processing apparatus.

### BACKGROUND

JP2014-139537A discloses a technique of imaging, by a scanning electron microscope (SEM), a circuit pattern present at a desired position on a semiconductor device in order to measure or inspect a semiconductor.

Patent Document 1: JP2014-139537A

### SUMMARY

A profile detection method according to an aspect of the present disclosure includes a region detection step, a boundary detection step, and a contour detection step. In the region detection step, data of an image in which a plurality of recesses recessed in one direction are arranged in an intersecting direction with respect to the one direction is analyzed to detect each recess region in the image. In the boundary detection step, the data is analyzed to detect a boundary of a film included in the image. In the contour detection step, the data is analyzed to detect a contour of the recess for the each recess region in the image.

### BRIEF DESCRIPTION OF DRAWINGS

FIG. 1 is a diagram showing an example of a functional configuration of an information processing apparatus according to an embodiment.

FIG. 2 is a diagram showing an example of an image in image data according to the embodiment.

FIG. 3A is a diagram showing an example of a method of detecting each recess region in the image according to the embodiment.

FIG. 3B is a diagram showing an example of the method of detecting each recess region in the image according to the embodiment.

FIG. 3C is a diagram showing an example of the method of detecting each recess region in the image according to the embodiment.

FIG. 4A is a diagram showing an example of a method of detecting a boundary of a film according to the embodiment.

FIG. 4B is a diagram showing an example of the method of detecting a boundary of a film according to the embodiment.

FIG. 4C is a diagram showing an example of the method of detecting a boundary of a film according to the embodiment.

FIG. 5 is a diagram showing an example of the method of detecting a boundary of a film according to the embodiment.

FIG. 6 is a flowchart showing an example of a processing flow of a profile detection program according to the embodiment.

### DETAILED DESCRIPTION

Hereinafter, embodiments of a profile detection method, a profile detection program, and an information processing apparatus disclosed in the present application will be described in detail with reference to the drawings. The disclosed profile detection method, profile detection program, and information processing apparatus are not limited by the present embodiment.

In the related art, a process engineer supports optimization of a recipe in a semiconductor manufacturing process. For example, whether the recipe is appropriate is determined by imaging, by a scanning electron microscope, a cross section of a semiconductor device in which a recess such as a trench or a hole is formed, and measuring a dimension such as a critical dimension (CD) of the recess in the captured image. The process engineer manually specifies a range of the recess in the captured image and manually specifies a position of a contour in which the dimension is to be measured, and a dimension measurement operation is person-dependent. As a result, it takes time to perform dimension measurement. In addition, since the measurement operation such as specifying of the position of the contour in which the dimension is to be measured is person-dependent, a person-dependent error may occur in the measured dimension. In addition, when it is attempted to measure dimensions of a large number of recesses, it takes time and effort.

Therefore, a technique for improving efficiency of the dimension measurement is expected.

### Embodiment

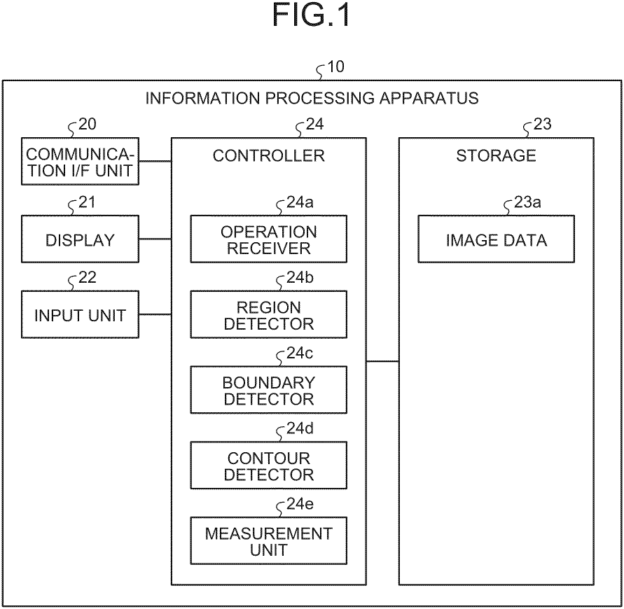

Embodiments will be described. Hereinafter, a case in which a dimension of a recess in a captured image is measured by an information processing apparatus 10 will be described as an example. FIG. 1 is a diagram showing an example of a functional configuration of the information processing apparatus 10 according to the embodiment. The information processing apparatus 10 is an apparatus that provides a function of measuring a dimension of a recess in a captured image. The information processing apparatus 10 is, for example, a computer such as a server computer or a personal computer. The process engineer uses the information processing apparatus 10 to measure the dimension of the recess in the captured image.

The information processing apparatus 10 includes a communication I/F (interface) unit 20, a display 21, an input unit 22, a storage 23, and a controller 24. The information processing apparatus 10 may include another device included in a computer in addition to the above devices.

The communication I/F unit 20 is an interface that performs communication control with other apparatuses. The communication I/F unit 20 is connected to a network (not shown), and transmits and receives various kinds of information to and from other apparatuses via the network. For example, the communication I/F unit 20 receives data of a digital image captured by a scanning electron microscope.

The display 21 is a display device that displays various kinds of information. Examples of the display 21 include display devices such as a liquid crystal display (LCD) and a cathode ray tube (CRT). The display 21 displays various kinds of information.

The input unit 22 is an input device that inputs various kinds of information. Examples of the input unit 22 include input devices such as a mouse and a keyboard. The input unit 22 receives an operation input from a user, such as a process engineer, and inputs operation information indicating the received operation content to the controller 24.

The storage 23 is a storage device such as a hard disk, a solid state drive (SSD), or an optical disk. The storage 23 may be a semiconductor memory capable of rewriting data, such as a random access memory (RAM), a flash memory, and a non volatile static random access memory (NVSRAM).

The storage 23 stores an operating system (OS) or various programs including a profile detection program to be executed by the controller 24, which will be described later. Further, the storage 23 stores various types of data used in the program executed by the controller 24. For example, the storage 23 stores image data 23a.

The image data 23a is data of an image obtained by imaging a cross section of a semiconductor device by the scanning electron microscope. The semiconductor device is formed on, for example, a substrate such as a semiconductor wafer. The image data 23a is acquired by imaging, by the scanning electron microscope, a cross section of the substrate on which the semiconductor device is formed.

The controller 24 is a device that controls the information processing apparatus 10. As the controller 24, an electronic circuit such as a central processing unit (CPU), a micro processing unit (MPU) and a graphics processing unit (GPU), or an integrated circuit such as an application specific integrated circuit (ASIC) and a field programmable gate array (FPGA) can be adopted. The controller 24 has an internal memory for storing programs defining various process procedures or control data, and executes various processes by the programs and the control data.

The controller 24 functions as various processors by the various programs operating. For example, the controller 24 includes an operation receiver 24a, a region detector 24b, a boundary detector 24c, a contour detector 24d, and a measurement unit 24e.

The operation receiver 24a receives various operations. For example, the operation receiver 24a displays an operation screen on the display 21, and receives, from the input unit 22, various operations on the operation screen. For example, the operation receiver 24a receives, from the operation screen, specifying of the image data 23a to be a profile detection target. The operation receiver 24a reads the specified image data 23a from the storage 23, and causes the display 21 to display an image of the read image data 23a. The operation receiver 24a receives, from the operation screen, an instruction for starting profile detection.

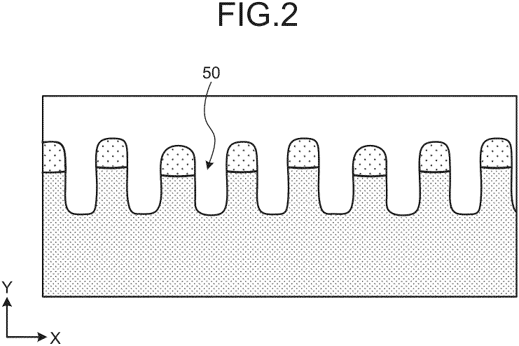

FIG. 2 is a diagram showing an example of the image of the image data 23a according to the embodiment. FIG. 2 is an image obtained by imaging, by the scanning electron microscope, a cross section of a semiconductor device in which a trench or a hole is formed. A horizontal direction of the image is defined as an x direction, and a vertical direction of the image is defined as a y direction. In the image shown in FIG. 2, a plurality of recesses 50 recessed in the y direction are formed side by side in the x direction. The recess 50 is, for example, a cross section of the trench or the hole formed in the semiconductor device.

For example, when determining whether the recipe is appropriate, the process engineer specifies, from the operation screen, the image data 23a of a cross section of a semiconductor device which has been subjected to substrate processing in a recipe whose appropriacy is to be determined. Then, the process engineer instructs the start of the profile detection from the operation screen.

When instructed to start the profile detection, the region detector 24b analyzes the specified image data 23a to detect a region in each recess 50 in the image.

For example, the region detector 24b performs a frequency analysis on the image in the x direction to specify a range of the image including the recesses 50 with respect to the y direction. For example, the region detector 24b performs the frequency analysis on the image in the x direction at each position in the y direction in the image, and specifies a range in which frequencies corresponding to the recesses 50 are obtained as the range of the image including the recesses 50 with respect to the y direction.

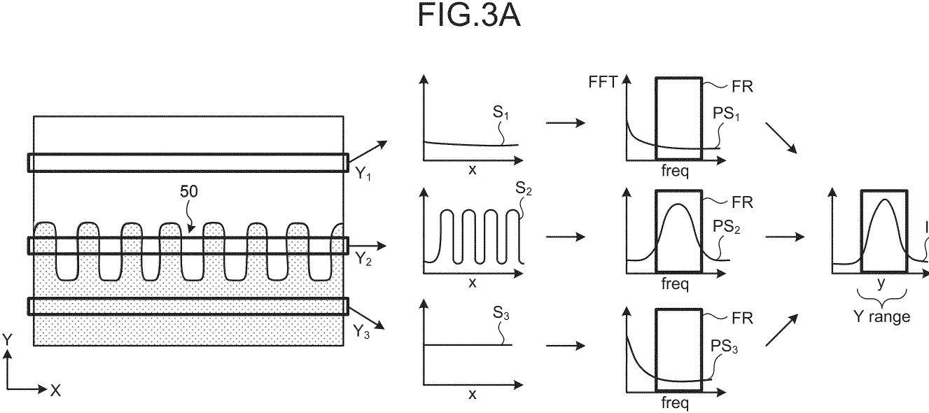

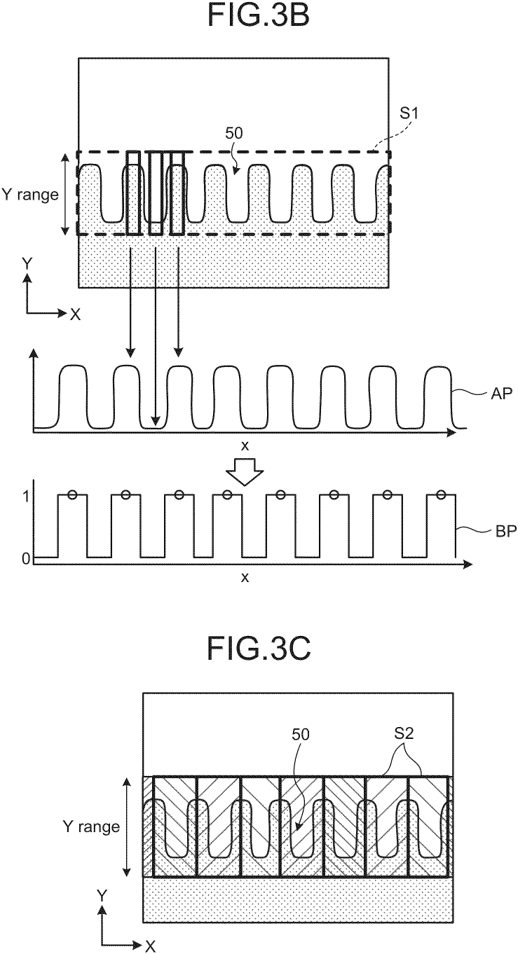

FIGS. 3A to 3C are diagrams showing examples of a method of detecting the region in the recess 50 in the image according to the embodiment. FIG. 3A shows an image in which the recesses 50 recessed in the y direction are formed side by side in the x direction. The region detector 24b obtains, at each position in the y direction in the image, a luminance profile in which luminances of pixels in the x direction in the image are arranged. Then, the region detector 24b performs fast Fourier transform (FFT) on the luminance profile at each position in the y direction in the image to obtain a power spectrum at each position in the y direction. FIG. 3A shows luminance profiles S₁, S₂, and S₃ in the x direction at positions y₁, y₂, and y₃ in the y direction, and power spectra PS₁, PS₂, and PS₃ at the positions y₁, y₂, and y₃. The region detector 24b integrates the power spectra at respective positions in the y direction within a range of the frequencies corresponding to the recesses 50 included in the image. The range of the frequencies corresponding to the recesses 50 may be input from the input unit 22, may be specified by analyzing the number of the recesses 50 included in the image, or may be specified based on design information of the semiconductor device in the image. For example, the region detector 24b obtains, based on the design information of the semiconductor device, a minimum value and a maximum value of the number of the recesses 50 assumed to be included in the image, and specifies a range of frequencies corresponding to the minimum value and the maximum value as the range of the frequencies corresponding to the recesses 50. The region detector 24b integrates the power spectra at respective positions in the y direction within the range of the frequencies corresponding to the recesses 50, and arranges integrated values of the power spectra at respective positions in the y direction in the order of the positions in the y direction to obtain an integrated value profile. In FIG. 3A, in the power spectra PS₁, PS₂, and PS₃, the range of the frequencies corresponding to the recesses 50 is indicated by a rectangle FR. In addition, FIG. 3A shows an integrated value profile IS in which the integrated values of the power spectra at respective positions in the y direction in the range of the rectangle FR are arranged in the order of the positions in the y direction.

The region detector 24b detects a maximum value of the integrated value profile IS. The region detector 24b specifies a range of a skirt of a peak including the detected maximum value as the range of the image including the recesses 50 with respect to the y direction. For example, the region detector 24b obtains a baseline of the integrated value profile IS, and specifies a range in which the peak is the baseline as the range of the image including the recesses 50 with respect to the y direction. Alternatively, the region detector 24b specifies a range in which a change in the integrated values from the peak including the maximum value is equal to or greater than a predetermined value as the range of the image including the recesses 50 with respect to the y direction. In FIG. 3A, the range of the skirt of the peak including the maximum value is indicated as a Y Range in the integrated value profile IS. The region detector 24b specifies the Y Range, as the range of the image including the recesses 50 with respect to the y direction.

The region detector 24b detects the region in the recess 50 from the specified range of the image. For example, the region detector 24b calculates, from the specified range of the image, an average value of luminances of pixels in the y direction for each position in the x direction in the image. The region detector 24b detects the region in the recess 50 from the specified range of the image based on the calculated average value at each position in the x direction.

FIG. 3B shows an image in which the recesses 50 recessed in the y direction are formed side by side in the x direction. In FIG. 3B, the y-direction range, i.e., the Y Range, in the image is indicated by a rectangle S1. The range indicated by the rectangle S1 includes the recesses 50. For example, the region detector 24b extracts a specified y-direction range, i.e., the Y Range in the image, and calculates, from an image of the extracted Y Range, the average value of the luminances of the pixels in the y direction for each position in the x direction in the image. The region detector 24b arranges the average values at respective positions in the x direction in the order of the positions in the x direction to obtain an average value profile. FIG. 3B shows an average value profile AP in which the average values at respective positions in the x direction are arranged in the order of the positions in the x direction.

The region detector 24b binarizes values in the average value profile AP in the x direction. For example, the region detector 24b obtains an average value of the average value profile in the x direction, and binarizes the values in the average value profile using the obtained average value as a threshold value. For example, the region detector 24b sets, as a first value, a value in the average value profile which is equal to or greater than the threshold value, sets, as a second value, a value in the average value profile which is smaller than the threshold value, and binarizes the values in the average value profile. FIG. 3B shows a profile BP obtained by setting, as [1], values in the average value profile AP which are equal to or greater than the threshold value (average value), setting, as [0], values in the average value profile AP which are smaller than the threshold value, and binarizing the values in the average value profile AP. The region detector 24b detects, for each continuous portion in which the first value is continuous in a profile after binarization, a center position in the continuous portion as a pattern boundary of the recess 50 in the x direction. For example, the region detector 24b detects, for each continuous portion in which [1] is continuous in the profile BP after binarization, a center position in the continuous portion as a pattern boundary of the recess 50 in the x direction. In FIG. 3B, [O] is indicated at the center position for each continuous portion in which [1] is continuous in the profile BP after binarization. The region detector 24b detects a region between detected pattern boundaries as the region in the recess 50 for the image of the Y Range. For example, the region in the recess 50 is detected by using the position indicated by [O] as the pattern boundary from the image of the Y Range shown in FIG. 3C. In FIG. 3C, the region in recess 50 detected from the image of the Y Range is indicated by a rectangle S2.

The boundary detector 24c analyzes the specified image data 23a to detect a boundary of a film included in the image.

For example, for the region in the recess 50 detected by the region detector 24b, the boundary detector 24c detects the boundary of the film based on a change in luminance of a side wall constituting the recess 50 in the y direction. For example, the boundary detector 24c obtains, for the region in the recess 50 detected by the region detector 24b, the change in luminance of the side wall constituting the recess 50 in the y direction. The boundary detector 24c detects a portion in which the change in luminance is large as the boundary of the film.

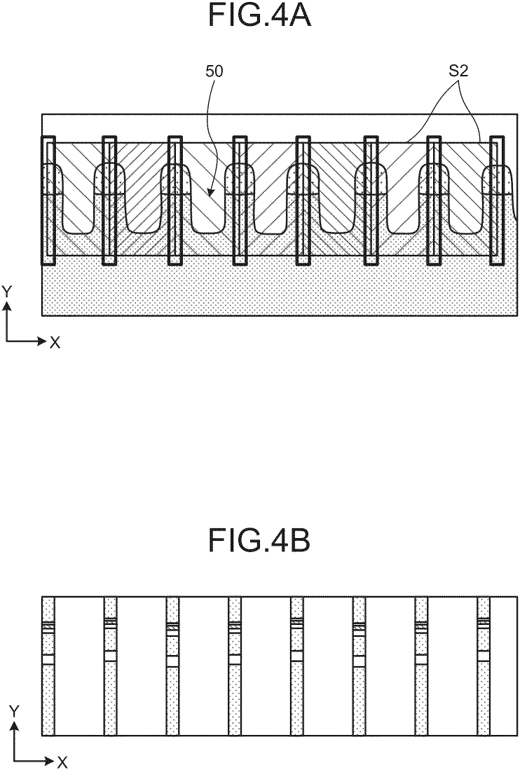

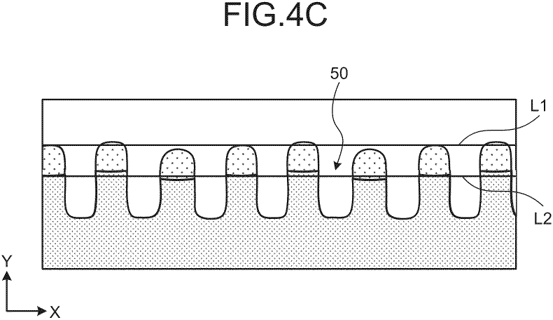

FIGS. 4A to 4C are diagrams showing examples of a method of detecting the boundary of the film according to the embodiment. FIG. 4A shows an image in which the recesses 50 recessed in the y direction are formed side by side in the x direction. In FIG. 4A, the region in the recess 50 is indicated by the rectangle S2. For example, the boundary detector 24c cuts out, from the image, an image of the y-direction range, i.e., the Y Range, in which the recesses 50 are included. The boundary detector 24c cuts out, from the cut out image of the Y Range, images of each regions in the vicinity of positions of the pattern boundaries of the recesses 50. The boundary detector 24c obtains, for each of the cut out images of the regions in the vicinity of the positions of the pattern boundaries, a change in luminance of pixels in the y direction, and detects, as a boundary position of the film, a position at which the change in luminance in the y direction has a peak. For example, the boundary detector 24c applies a differentiation filter in the y direction to the cut out image of the region in the vicinity of the position of the pattern boundary, and calculates a differential image. Examples of the differentiation filter include a Sobel filter. FIG. 4B shows an example of the differential image obtained by obtaining the changes in luminance in the y direction in the regions in the vicinity of the positions of the pattern boundaries of the recesses 50 in the image. In the differential image, portions in which the change in luminance is large are shown in white. The boundary detector 24c obtains, for the recess 50, a position in the y direction in the portion in which the change in luminance is large, and detects an average position in the y direction as the boundary of the film. In FIG. 4C, the films constituting the side walls of the recesses 50 are shown in different patterns, and the detected boundaries of the films in the y direction are indicated by lines L1 and L2. The film on an upper side of the recess 50 in the image is, for example, a mask. The boundary detector 24c can detect the boundary of the film. By detecting the boundary of the film in this manner, the boundary can be used for automatic adjustment of rotational deviation of the image. For example, the boundary detector 24c may use the line L2 as the boundary of the film to perform rotation correction on the image such that the line L2 is horizontal. Accordingly, the rotational deviation of the image can be corrected, and a positional relation, a film thickness, and the like of the films can be easily understood from the image.

The contour detector 24d analyzes the specified image data 23a to detect a contour of the recess 50 for the region in the recess 50 in the image. For example, the contour detector 24d detects, for the region in the recess 50 detected by the region detector 24b, the contour of the recess 50 based on a change in luminance in the x direction.

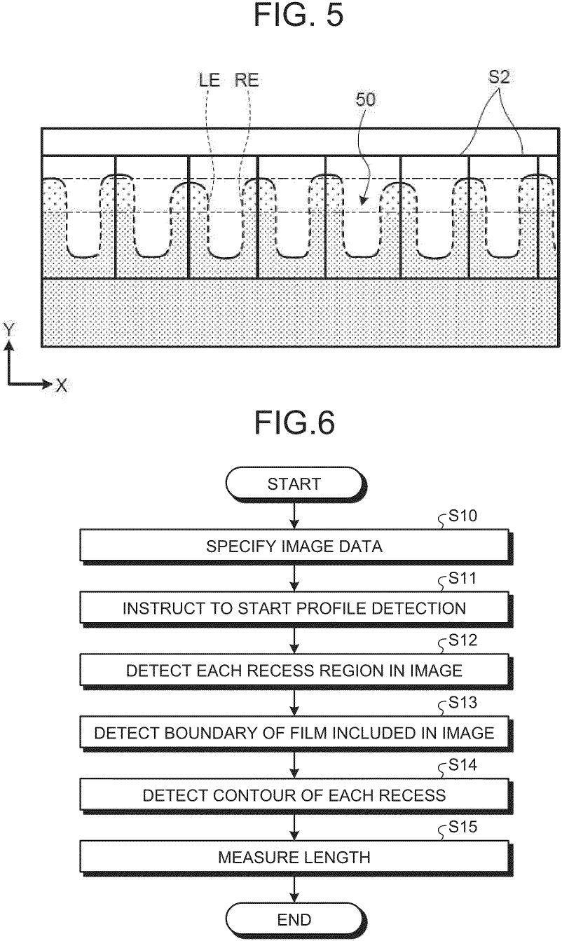

FIG. 5 is a diagram showing an example of the method of detecting a boundary of a film according to the embodiment. For example, the contour detector 24d cuts out, from an image, an image of the y-direction range, i.e., the Y Range, in which the recesses 50 are included. The contour detector 24d obtains, from the cut out image of the Y Range, a luminance profile of pixels in the x direction for each position in the y direction in the image. The contour detector 24d applies a change point detection algorithm such as a secondary differential filter to the luminance profile at each position in the y direction, and specifies a position of a left edge LE and a position of a right edge RE, thereby specifying an edge profile of a left-right contour of each recess 50. For example, the contour detector 24d applies a secondary differential filter to the luminance profile at each position in the y direction to specify a portion in which the change in luminance is large. The contour detector 24d detects, for the region in the recess 50, the edge profile of the left-right contour by specifying, in the region in the recess 50, a portion in which the change in luminance is large on the left side as the position of the left edge LE and a portion in which the change in luminance is large on the right side as the position of the right edge RE. The contour detector 24d identifies, for the region in the recess 50, a y-direction uppermost position in the detected left-right contour as a profile upper end and a y-direction lowermost position in the detected left-right contour as a profile lower end. The contour detector 24d can obtain, for the region in the recess 50, a final edge profile of the contour of the recess 50 by trimming the edge profile of the left-right contour at the upper and lower ends.

Since the information processing apparatus 10 according to the embodiment can automatically detect the range of the recess 50 or the contour of the recess 50 in the image in this manner, the efficiency of the dimension measurement can be improved.

The measurement unit 24e measures the dimension. For example, the operation receiver 24a causes the display 21 to display the image in which the contour of the recess 50 is detected by the contour detector 24d, and receives, from the input unit 22, specifying of a position of the contour of the recess 50 at which the dimension is to be measured. The measurement unit 24e measures a CD of the recess 50 at the specified position of the contour.

The measurement unit 24e may measure the dimension of the recess 50 such as a CD at a predetermined position of the contour without receiving the specifying of the position. The position at which the dimension is to be measured may be set in advance or may be set based on detection results of the boundary detector 24c or the contour detector 24d. For example, the measurement unit 24e may measure, at a position of a height of the boundary of the film detected by the boundary detector 24c, the dimension such as a CD at the boundary of the film from the contour of each recess 50 detected by the contour detector 24d. The measurement unit 24e may measure the dimension such as a CD at each position in the y direction from the edge profile of the contour of each recess 50 detected by the contour detector 24d.

The measurement unit 24e may cause the display 21 to display the measured dimension together with the measurement position, may store, in the storage 23, data of the measured dimension together with the measurement position, or may transmit the data to another apparatus via the communication I/F unit 20.

Since the information processing apparatus 10 according to the embodiment can measure the dimension of the recess 50 in the image in this manner, the efficiency of the dimension measurement can be improved. As a result, the time taken to measure the dimensions can be shortened. Since the information processing apparatus 10 can detect the contour that is the position at which the dimension is to be measured, it is possible to reduce the person-dependent error that occurs in the measured dimension. The information processing apparatus 10 can efficiently measure the dimensions of a large number of recesses 50. For example, by automatically measuring the dimension of each recess 50 included in the image, a large number of length measurement values used for data analysis can be collected. An abnormal recess 50 can be detected by automatically measuring the dimension of each recess 50 included in the image and analyzing the measured dimension of each recess 50.

### [Processing Flow]

Next, a flow of a profile detection method according to the embodiment will be described. The information processing apparatus 10 according to the embodiment performs the profile detection method by executing the profile detection program. FIG. 6 is a flowchart showing an example of a processing flow of a profile detection program according to the embodiment.

The operation receiver 24a receives, from the operation screen, specifying of the image data 23a as a profile detection target (step S10). The operation receiver 24a receives, from the operation screen, the instruction for starting the profile detection (step S11).

The region detector 24b analyzes the specified image data 23a to detect the region in the recess 50 in the image (step S12). For example, the region detector 24b performs a frequency analysis on the image in the x direction to specify a range of the image including the recesses 50 with respect to the y direction. Then, the region detector 24b detects the region in the recess 50 from the specified range of the image.

The boundary detector 24c analyzes the specified image data 23a to detect the boundary of the film included in the image (step S13). For example, for the region in the recess 50 detected by the region detector 24b, the boundary detector 24c detects the boundary of the film based on a change in luminance of a side wall constituting the recess 50 in the y direction.

The contour detector 24d analyzes the specified image data 23a to detect the contour of the recess 50 for the region in the recess 50 in the image (step S14). For example, the contour detector 24d detects, for the region in the recess 50 detected by the region detector 24b, the contour of the recess 50 based on a change in luminance in the x direction.

The measurement unit 24e measures the dimension (step S15) and ends the processing. For example, the operation receiver 24a causes the display 21 to display the image in which the contour of the recess 50 is detected by the contour detector 24d, and receives, from the input unit 22, specifying of a position of the contour of the recess 50 at which the dimension is to be measured. The measurement unit 24e measures a CD of the recess 50 at the specified position of the contour.

As described above, the profile detection method according to the embodiment includes a region detection step (step S12), a boundary detection step (step S13), and a contour detection step (step S14). In the region detection step, data (image data 23a) of an image in which the recesses 50 recessed in one direction (y direction) are arranged in an intersecting direction (x direction) with respect to the one direction is analyzed to detect the region in the recess 50 in the image. In the boundary detection step, the data is analyzed to detect a boundary of a film included in the image. In the contour detection step, the data is analyzed to detect a contour of the recess 50 for the region in the recess 50 in the image. Accordingly, the profile detection method according to the embodiment can improve efficiency of dimension measurement. For example, the profile detection method according to the embodiment can shorten the time taken to measure a dimension. Further, the profile detection method according to the embodiment can reduce a person-dependent error that occurs in the measured dimension. In addition, the profile detection method according to the embodiment can efficiently measure dimensions of a large number of recesses 50.

In the region detection step, a frequency analysis is performed on the image in the intersecting direction to specify a range of the image including the recesses 50 with respect to the one direction, and the region in the recess 50 is detected from the specified range of the image. In the region detection step, the frequency analysis on the image is performed in the intersecting direction at each position in the one direction of the image, and a range in which frequencies corresponding to the recesses 50 are obtained is specified as the range of the image including the recesses 50 with respect to the one direction. Accordingly, the profile detection method according to the embodiment can accurately specify the range of the image including the recesses 50 with respect to the one direction, and can detect the region in the recess 50 from the specified range of the image.

In the region detection step, an average value of luminances of pixels in the one direction is calculated from the specified range of the image for each position in the intersecting direction of the image, and the region in the recess 50 is detected from the specified range of the image based on the calculated average value at each position in the intersecting direction. Accordingly, the profile detection method according to the embodiment can accurately detect the region in the recess 50 from the specified range of the image.

In the boundary detection step, for the region in the recess 50 detected in the region detection step, the boundary of the film is detected based on a change in luminance of a side wall constituting the recess 50 in the one direction. In the boundary detection step, the change in luminance of the side wall in the one direction is obtained, and a portion in which the change is large is detected as the boundary of the film. Accordingly, the profile detection method according to the embodiment can accurately detect the boundary of the film.

In the contour detection step, for the region in the recess 50 of the image, the contour of the recess 50 is detected based on a change in luminance in the intersecting direction. In the contour detection step, for the region in the recess 50 of the image, the change in luminance in the intersecting direction is obtained at each position in the one direction, and a portion in which the change is large is detected as the contour of the recess 50. Accordingly, the profile detection method according to the embodiment can accurately detect the contour of the recess 50.

Hitherto, the embodiment has been described above. The embodiment disclosed herein is illustrative and should not be construed as limiting in all aspects. The embodiment described above may be embodied in various forms. The embodiment described above may be omitted, replaced, or modified in various forms without departing from the scope and spirit of the claims.

For example, in the above embodiment, the case in which the region detection (step S12), the boundary detection (step S13), and the contour detection (step S14) are sequentially performed has been described as an example. However, the present disclosure is not limited thereto. The order of the region detection, the boundary detection, and the contour detection may be different. For example, the method may be performed in the order of the contour detection, the region detection, and the boundary detection. For example, the method may be performed in the following order. The contour detector 24d performs a binarization process on an entire image of the specified image data 23a to acquire a binary image, and specifies, from the binary image, an outer contour of the recess that is the boundary. For example, the contour detector 24d specifies, as the contour, a pixel that is a binary boundary of the binary image. Similar to the region detection according to the above embodiment, the region detector 24b analyzes the specified image data 23a to detect the region in the recess 50 of the image. Similar to the region detection according to the above embodiment, the boundary detector 24c analyzes the image data 23a to detect the boundary of the film included in the image.

The region detection, the boundary detection, and the contour detection may be performed in parallel with each other regardless of the order, or may be performed by combining two or more processes. Detection results may be used mutually. For example, when the region detection is performed, the region detection may be performed using the binary image obtained by the contour detection.

In the above embodiment, the case in which the dimensions of the recesses of the semiconductor device formed on the substrate such as a semiconductor wafer are measured has been described as an example. However, the present disclosure is not limited thereto. The substrate may be any substrate such as a glass substrate. The profile detection method according to the embodiment may be applied to dimension measurement for a recess in any substrate. For example, the profile detection method according to the embodiment may be applied to dimension measurement for a recess formed in a substrate for an FPD.

It shall be understood that the embodiments disclosed herein are illustrative and are not restrictive in all aspects. Indeed, the above-described embodiments can be implemented in various forms. The embodiments described above may be omitted, replaced, or modified in various forms without departing from the scope and spirit of the appended claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

### Advantageous Effects of the Invention

According to the present disclosure, it is possible to improve efficiency of dimension measurement.

1. A profile detection method, comprising:
region detecting, by analyzing data of an image in which a plurality of recesses recessed in one direction are arranged in an intersecting direction with respect to the one direction, each recess region in the image;
boundary detecting a boundary of a film included in the image by analyzing the data; and
contour detecting a contour of the recess for the each recess region in the image by analyzing the data.

2. The profile detection method according to claim 1, wherein
the region detecting including detecting, a frequency analysis is performed on the image in the intersecting direction to specify a range of the image including the plurality of recesses with respect to the one direction, and the each recess region is detected from the specified range of the image.

3. The profile detection method according to claim 2, wherein
the region detecting includes detecting, the frequency analysis on the image is performed in the intersecting direction at each position in the one direction of the image, and a range in which frequencies corresponding to the plurality of recesses are obtained is specified as the range of the image including the plurality of recesses with respect to the one direction.

4. The profile detection method according to claim 3, wherein
the region detecting includes detecting, an average value of luminances of pixels in the one direction is calculated from the specified range of the image for each position in the intersecting direction of the image, and the each recess region is detected from the specified range of the image based on the calculated average value at each position in the intersecting direction.

5. The profile detection method according to claim 4, wherein
the boundary detecting includes detecting, for the each recess region detected in the region detection step, the boundary of the film is detected based on a change in luminance of a side wall constituting the recess in the one direction.

6. The profile detection method according to claim 5, wherein
the boundary detecting includes detecting, a change in luminance of the side wall in the one direction is obtained, and a portion in which the change is large is detected as the boundary of the film.

7. The profile detection method according to claim 6, wherein
the contour detecting includes detecting, for the each recess region in the image, the contour of the recess is detected based on a change in luminance in the intersecting direction.

8. The profile detection method according to claim 7, wherein
the contour detecting includes detecting, for the each recess region in the image, the change in luminance in the intersecting direction is obtained at each position in the one direction, and a portion in which the change is large is detected as the contour of the recess.

9. The profile detection method according to claim 8, further comprising:
measuring a dimension of the recess based on a detection result of the contour detecting.

10. The profile detection method according to claim 9, wherein
the data of the image is data of an image of a cross section of a substrate acquired by a scanning electron microscope.

11. A non-transitory computer-readable recording medium having stored therein a profile detection program that causes a computer to execute a process comprising:
region detecting, by analyzing data of an image in which a plurality of recesses recessed in one direction are arranged in an intersecting direction with respect to the one direction, each recess region in the image;
boundary detecting a boundary of a film included in the image by analyzing the data; and
contour detecting a contour of the recess for the each recess region in the image by analyzing the data.

12. An information processing apparatus, comprising:
a region detector configured to detect, by analyzing data of an image in which a plurality of recesses recessed in one direction are arranged in an intersecting direction with respect to the one direction, each recess region in the image;
a boundary detector configured to detect a boundary of a film included in the image by analyzing the data; and
a contour detector configured to detect a contour of the recess for the each recess region in the image by analyzing the data.

13. The profile detection method according to claim 2, wherein
the region detecting includes detecting, an average value of luminances of pixels in the one direction is calculated from the specified range of the image for each position in the intersecting direction of the image, and the each recess region is detected from the specified range of the image based on the calculated average value at each position in the intersecting direction.

14. The profile detection method according to claim 1, wherein
the boundary detecting includes detecting, for the each recess region detected in the region detection step, the boundary of the film is detected based on a change in luminance of a side wall constituting the recess in the one direction.

15. The profile detection method according to claim 1, wherein
the contour detecting includes detecting, for the each recess region in the image, the contour of the recess is detected based on a change in luminance in the intersecting direction.

16. The profile detection method according to claim 1, further comprising:
measuring a dimension of the recess based on a detection result of the contour detecting.

17. The profile detection method according to claim 1, wherein
the data of the image is data of an image of a cross section of a substrate acquired by a scanning electron microscope.
